(19) United States
(12) Patent Application Publication
(10) Pub. No.: US 2008/0101893 A1
(43) Pub. Date: May 1, 2008

(54) VACUUM PROCESSING APPARATUS AND A METHOD FOR VENTING TO ATMOSPHERE

(75) Inventor: Hiromitsu Tanzawa, Sayama-shi (JP)

Correspondence Address: WOODCOCK WASHBURN LLP, CIRA CENTRE, 12TH FLOOR, 2929 ARCH STREET, PHILADELPHIA, PA, 19104-2891, US

(73) Assignee: NIHON DEMPA KOGYO CO., LTD., Shibuya-ku (JP)

(21) Appl. No.: 11/858,481

(22) Filed: Sep. 20, 2007

(30) Foreign Application Priority Data
Sep. 21, 2006 (JP) 2006-256237

(51) Int. Cl. H01L 21/67; F16J 12/00

(52) U.S. Cl. 414/217.1; 277/628

(57) ABSTRACT

To provide a vacuum processing apparatus, wherein only a chamber having a lower vacuum pressure, is vented to atmosphere, in case the chamber having the lower vacuum pressure, requires maintenance and such. Disclosed is a vacuum processing apparatus comprising a first vacuum chamber evacuated to a predetermined vacuum pressure; a second vacuum chamber evacuated to a lower vacuum pressure than the first vacuum chamber; a gate lock chamber connecting the first vacuum chamber and the second vacuum chamber; a first gate valve (GV1) opening and closing between the first vacuum chamber and the gate lock chamber; and a second gate valve (GV2) opening and closing between the second vacuum chamber and the gate lock chamber.

### CROSS-REFERENCE TO RELATED PATENT APPLICATION

This application claims the benefit of Japanese Patent Application No. 2006-256237 filed on Sep. 21, 2006 in the Japan Patent Office, the disclosure of which is incorporated herein in its entirety by reference.

### FIELD OF THE INVENTION

The present invention relates to vacuum processing apparatuses used for processing substrates, such as semiconductor wafers and quartz wafers, in various processes and to a method for venting vacuum chambers to atmosphere.

### BACKGROUND OF THE INVENTION

In vacuum processing apparatuses used for semiconductor manufacturing processes and quartz oscillator manufacturing processes, chambers have been known to be used; e.g., chambers comprising transfer robots inside (transfer chambers) and various process chambers for vacuum processing. In order to evacuate such transfer chambers and/or processing chambers, wet and/or dry pumps have been used, including rotary pumps, scroll pumps, diffusion pumps and turbo-molecular pumps. Gate lock chambers (transfer paths) are provided for taking out and putting in substrates, between the transfer chambers and process chambers, or between the transfer chambers and exterior portions. The gate lock chambers are equipped with gate valves which keep the differential pressure between the transfer chambers and process chambers.

The process chambers, used for the vacuum sealing of quartz oscillators, or sputtering, for example, requires various vacuum pressures depending on their applications and generally operates at vacuum pressures from about 1×10-2 Pa to about 1×10-4 Pa. The transfer chambers, which transfer semiconductor wafers, or quartz wafers, to the process chambers, operate at vacuum pressures one to three orders of magnitude higher (1×101 Pa to about 1×10-1 Pa) than those for the process chambers. Although it is possible to lower the vacuum pressures inside the transfer chambers by evacuating with turbo-molecular pumps, the additional turbo-molecular pumps for the transfer chambers, which do not require turbo-molecular pumps, make the apparatus costs higher.

The transfer chambers and process chambers require maintenance work, not only for failure recovery, but also for periodic parts replacement. In case a plurality of transfer chambers and/or process chambers are connected with each other, venting a chamber, having a lower vacuum pressure, to atmospheric pressure (so called “vacuum breaking”, or “venting to atmosphere”) requires venting of a transfer chamber, or a process chamber, having a higher vacuum pressure, to atmospheric pressure. This is because the gate valves are closed by the differential pressure in the direction from the higher vacuum pressure to the lower vacuum pressure.

As a result, when replacing a part in a chamber, having a lower vacuum pressure, substrates in a transfer chamber, having a higher vacuum pressure, have to be removed. This lowers work efficiency. In addition, all the chambers, vented to atmospheric pressure, have to be evacuated again to predetermined vacuum pressures.

### SUMMARY OF THE INVENTION

The present invention has been made keeping in mind the above described problems and, therefore, it is the object of the present invention to provide a vacuum processing apparatus, in which, at the time of a maintenance work on a chamber, having a lower vacuum pressure, only the chamber, having the lower vacuum pressure, is vented to atmospheric pressure.

A vacuum processing apparatus according to a first aspect comprises; a first vacuum chamber, having a predetermined vacuum pressure; a second vacuum chamber being different from the first chamber; a gate lock chamber connecting the first vacuum chamber and the second vacuum chamber; a first gate valve opening and closing between the first vacuum chamber and the gate lock chamber; and a second gate valve opening and closing between the second vacuum chamber and the gate lock chamber. In this configuration, when only the first vacuum chamber, or only the second vacuum chamber, is vented to atmospheric pressure, the first gate valve, or the second gate valve, keeps the vacuum pressure of the second vacuum chamber, or the first vacuum chamber, respectively. Conventionally, when one of the chambers is vented to atmospheric pressure, the other chambers also have to be vented to the atmospheric pressure; however the present invention allows the venting of only one of the chambers.

In the vacuum processing apparatus, according to a second aspect, the first vacuum chamber may have a vacuum pressure higher than that of the second vacuum chamber. In this configuration, when only the second vacuum chamber, having a lower vacuum pressure, is vented to atmospheric pressure, the second gate valve keeps the vacuum pressure of the first vacuum chamber.

In a third aspect of the vacuum processing apparatus, the gate lock chamber may further comprise a pipeline open to atmosphere and an open/close valve opening and closing the pipeline. In this configuration, in case that the second gate valve opens and then closes on the side of the second vacuum chamber, having a lower vacuum pressure, for example, the vacuum pressure inside the gate lock chamber becomes low. Under this condition, the first gate valve of the first vacuum chamber, having a higher vacuum pressure, may not open because of the differential pressure. In such a case, the open/close valve may be gradually opened to increase the vacuum pressure inside the gate lock chamber to a level equal to, or higher than, the vacuum pressure of the first vacuum chamber. Also, in case that the first vacuum chamber and the second vacuum chamber have high vacuum pressures and the vacuum pressure inside the gate lock chamber is lower, the gate valve may be opened by using the open/close valve.

In a fourth aspect of the vacuum processing apparatus, at least one of the first gate valve and the second gate valve, may comprise a projecting portion(s) projecting toward the gate lock chamber. This configuration reduces the volume inside the gate lock chamber. As a result, the gate lock chamber is evacuated, or vented, in a short period of time.

In a fifth aspect, the vacuum processing apparatus may comprise at least a sealing member, one disposed between the first gate valve and the first vacuum chamber and/or another disposed between the second gate valve and the second vacuum chamber. In this configuration, when venting one of the first vacuum chamber and the second vacuum chamber to atmosphere, one of the first gate valve and the second gate valve is pressed firmly to the sealing member(s) by atmospheric pressure.

In a sixth aspect, a method is provided, for a vacuum apparatus comprising a first vacuum chamber, having a predetermined vacuum pressure, and a second vacuum chamber, having a vacuum pressure lower than that of the first vacuum chamber, for venting only the second chamber to atmosphere. There are disposed a first gate valve, opening and closing between the first vacuum chamber and a gate lock chamber connecting between the first vacuum chamber and the second gate chamber, and a second gate valve, opening and closing between the first vacuum chamber and the gate lock chamber, to vent the second chamber to atmosphere by supplying gas from the vent valve of the second vacuum chamber. In this configuration, when only the second vacuum chamber, having a lower vacuum pressure, is vented to atmospheric pressure, the second gate valve keeps the vacuum pressure of the first vacuum chamber.

According to the present invention, as explained above, in case that a plurality of vacuum chambers are connected with each other and a chamber, having a lower vacuum pressure, is vented to atmospheric pressure, chambers, evacuated to higher vacuum pressures, need not to be vented to atmospheric pressure. According to the present invention, only the chamber, evacuated to a lower vacuum pressure, is vented to atmospheric pressure. As a result, works, such as wafer substrates, in the chambers, evacuated to higher vacuum pressures, need not to be taken out from the chambers, having higher vacuum pressures, and therefore operation efficiency is improved.

### BRIEF DESCRIPTION OF THE DRAWINGS

These and other features of the present invention will become apparent through the explanations of the following embodiments and be clearly defined by the appended claims. Various advantages which may not be described in this specification will become apparent to those skilled in the art.

FIG. 1 is a schematic configuration diagram of the vacuum processing system SYS according to the present invention.

FIG. 2 shows the configuration of piping and pumps for evacuating the first transfer chamber 22-A and the first processing unit UNI-A.

FIG. 3 is a flow chart showing the evacuating operation of the first transfer chamber 22-A and the first sputtering treatment chamber 42-A.

FIG. 4 shows a cross sectional view of the gate valve GV and gate lock chamber 70 according to a first embodiment.

FIG. 5 shows the operation of the gate valve GV according to a first embodiment.

FIG. 6 shows the operation of the gate valve GV according to a second embodiment.

### DETAILED DESCRIPTION OF ILLUSTRATIVE EMBODIMENTS

Configuration of Vacuum Processing System SYS

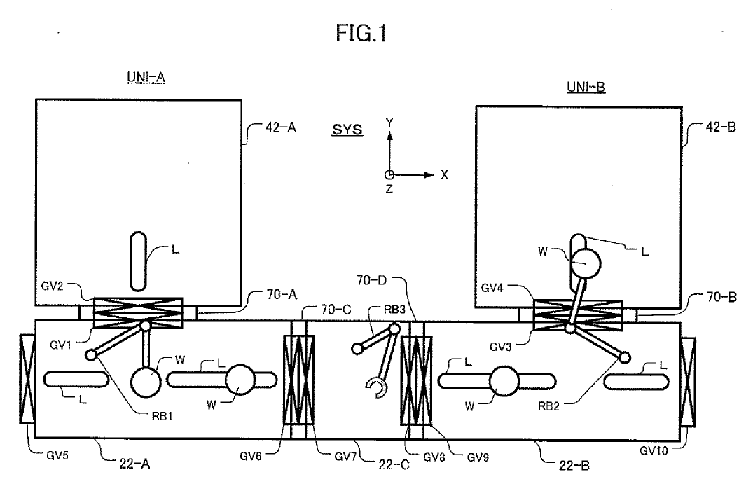

A preferred embodiment of the vacuum processing system SYS according to the present invention is explained in detail as follows with reference to appended drawings. FIG. 1 is a schematic configuration diagram of the vacuum processing system SYS according to the present invention. As shown in the diagram, the vacuum processing system SYS mainly comprises a first processing unit UNI-A, for providing a first treatment on a work, e.g., quartz wafer W, and a second processing unit UNI-B, for providing a second treatment. In this exemplary case, a chromium layer (Cr layer) is sputtered on the quartz oscillator, formed on a quartz wafer W, in the first processing unit UNI-A and a gold layer (Au layer) is sputtered in the second processing unit UNI-B. Incidentally, the following explains a case, in which one piece of quartz wafer W is treated, however, the explanation also applies to such cases that a plurality of quartz oscillators are placed on a palette, or a plurality of quartz wafers W are placed on a palette. Incidentally, in the present embodiment, a low vacuum pressure, or a high vacuum pressure, should be construed as vacuum pressures of the two vacuum chambers in a relative sense.

The first processing unit UNI-A, comprises; a first sputtering treatment chamber 42-A, in which Cr is continuously sputtered; a first transfer chamber 22-A transferring in and out the quartz wafer W to and from the treatment chambers 42; and a gate lock chamber 70-A keeping the difference in the vacuum pressure between the first transfer chamber 22-A and the first sputtering treatment chamber 42-A. The first sputtering treatment chamber 42-A is configured in such a way that supply of deposition gas and evacuation are made possible, and, in the chamber, there are provided a support (susceptor), onto which the quartz wafer W is mounted, and a loader L. The first gate lock chamber 70-A comprises a gate valve GV1 and a gate valve GV2 which open and close in airtight manners.

The first transfer chamber 22-A is configured in such a way that the chamber is evacuated to create a vacuum and, in the chamber, there is provided a multi-joint, transfer robot RB1 which is made to be, e.g., bendable, stretchable and rotatable, so that the quartz wafer W is sent or received. Within the inside, there is provided a station, or a loader L, to send and receive the quartz wafer W mounted thereon. The loader L may comprise, as needed, a cooling jacket to cool down a treated quartz wafer W, or a heating lamp to pre-heat a quartz wafer W before treatment. In order to transfer a quartz wafer W from a front-end to the first processing unit UNI-A, the first transfer chamber 22-A comprises a gate valve GV-5.

On the other hand, the second processing unit UNI-B, comprises a second sputtering treatment chamber 42-B for sputtering Au layers; a second transfer chamber 22-B transferring in and out the quartz wafer W to and from the treatment chamber 42-B; and a gate lock chamber 70-B keeping the difference in the vacuum pressure between the second transfer chamber 22-B and the second sputtering treatment chamber 42-B. The second sputtering treatment chamber 42-B is configured in such a way that evacuation is made possible, and, in the chamber, there are provided a support (susceptor), onto which the quartz wafer W is mounted, and a loader L. The second gate lock chamber 70-B comprises a gate valve GV3 and a gate valve GV4 which open and close in airtight manners.

The second transfer chamber 22-B is configured in such a way that the chamber is evacuated to create a vacuum and, in the chamber, there is provided a multi-joint, transfer robot RB2 which is made to be, e.g., bendable, stretchable and rotatable, so that the quartz wafer W is sent or received. Within the inside, there is provided a station, or a loader L, to send and receive the quartz wafer W mounted thereon. There is provided a gate valve GV10 to transfer the quartz wafer W from the second processing unit UNI-B, to a back end.

In addition, the vacuum processing system SYS comprises a third transfer chamber 22-C disposed between the first transfer chamber 22-A and the second transfer chamber 22-B. The third transfer chamber 22-C is also configured in such a way that the chamber is evacuated to create a vacuum and, in the chamber, there is provided a multi-joint, transfer robot RB3 which is made to be, e.g., bendable, stretchable and rotatable, so that the quartz wafer W is sent or received. The system comprises a third gate lock chamber 70-C between the third transfer chamber 22-C and the first transfer chamber 22-A, and a fourth gate lock chamber 70-D between the third transfer chamber 22-C the second transfer chamber 22-B. The third gate lock chamber 70-C comprises a gate valve GV-6 and a gate valve GV-7, which open and close in air-tight manners, on both its sides, while the fourth gate lock chamber 70-D comprises a gate valve GV-8 and a gate valve GV-9, which open and close in air-tight manners, on both its sides.

The Operation of the Vacuum Processing System SYS

The following explains the operation of the vacuum system SYS configured as described above. Firstly, nitrogen is supplied to the first transfer chamber 22-A to vent the camber to atmosphere. Subsequently, the gate valve GV-5 is opened and an untreated quartz wafer W, under atmospheric pressure, is transferred into the first transfer chamber 22-A. After the quartz wafer W is transferred into the first transfer chamber 22-A, the gate valve GV-5 is closed and the first transfer chamber 22-A is evacuated to a predetermined vacuum pressure. After this, the quartz wafer, placed at a predetermined position within the first transfer chamber 22-A, is mounted onto the fork portion of the transfer robot RB1.

Next, the gate valve GV1 and the gate valve GV2 of the first gate lock chamber 70-A are opened. Subsequently, the first transfer chamber 22-A is evacuated to a same vacuum as the first sputtering treatment chamber 42-A. The quartz wafer W, mounted on the fork portion of the transfer robot RB1, is transferred to the loader L in the first sputtering treatment chamber 42-A. After the above transfer of the wafer W is completed, the fork portion of the transfer robot RB1 returns to the first transfer chamber 22-A. Then, the gate valve GV1 and the gate valve GV2 of the first gate lock chamber 70-A are closed again. A Cr layer is deposited onto the quartz wafer W under a predetermined condition in the first sputtering process chamber 42-A. In order to transfer the processed quartz wafer W back to the first transfer chamber 22-A, the gate valve GV1 and the gate valve GV2 of the first gate lock chamber are opened. Then the quartz wafer W is retrieved to the first transfer chamber 22-A from the first sputtering process chamber 42-A by the transfer robot RB1. After this, the gate valve GV1 and gate valve GV2 are closed.

The quartz wafer W, then, is transferred from the first transfer chamber 22-A to the second transfer chamber 22-B, via the third transfer chamber 22-C. When the quartz wafer W is transferred from the first transfer chamber 22-A to the third transfer chamber 22-C, the vacuum pressure of the third transfer chamber 22-C becomes equal to that of the first transfer chamber 22-A. Then the gate valve GV6 and the gate valve GV7 of the third gate lock chamber are opened. After the transfer robot BR3, in the third transfer chamber, transfers the quartz wafer W from the first transfer chamber 22-A to the third transfer chamber 22-C, the gate valve GV6 and gate valve GV7 are closed. Subsequently, the second transfer chamber is evacuated to the same vacuum pressure as that of the first transfer chamber 22-A. The gate valve GV8 and gate valve GV9 are then opened. After the transfer robot BR3 transfers the quartz wafer W from the third transfer chamber 22-C to the second transfer chamber 22-B, the gate valve GV8 and gate valve GV9 are closed.

The third chamber 22-C is not necessarily required. Especially, in case that the first processing unit UNI-A, requires almost the same vacuum pressure as required by the second processing unit UNI-B, there is no need to provide the third transfer chamber 22-C. On the other hand, in case that the vacuum pressures required by the first processing unit UNI-A, and the second processing unit UNI-B are different by the order of two, it is preferable to provide the third transfer chamber 22-C, considering the period of time required for pumping down to the vacuum pressures.

The second processing unit UNI-B, operates almost the same manner as the first processing unit UNI-A. The quartz wafer positioned in the second transfer chamber 22-B is mounted on the fork portion of the transfer robot RB2. The gate valve GV3 and gate valve GV4 of the second gate lock chamber open, and quartz wafer W is mounted on the loader L of the second sputtering treatment chamber 42-B. While the quartz wafer W is mounted on the loader, the second transfer chamber is evacuated to a vacuum pressure almost same as that of the second sputtering chamber 42-B. And then, the gate valve GV3 and the gate valve GV4 of the second gate lock chamber 70-B are closed. An Au layer is deposited onto the quartz wafer W under a predetermined condition in the second sputtering process chamber 42-B. The processed quartz wafer W is transferred back to the second transfer chamber 22-B. After this, the quartz wafer W is transferred out from the gate valve 10.

Venting the Sputtering Treatment Chambers to Atmosphere

As described above, the vacuum processing system, SYS, comprises two gate valves between chambers, evacuated to different vacuum pressures. This configuration allows venting of a chamber, having a lower vacuum pressure, to atmosphere, without venting the other chamber, having a vacuum pressure higher than the lower vacuum pressure, to atmosphere. This will be explained in relation to the first transfer chamber 22-A and the first sputtering treatment chamber 42-A. In case that there is no gate valve GV2, the gate valve GV1 is pressed from the side of the first sputtering treatment chamber 42-A, because the first transfer chamber is in a vacuum state. As a result, the vacuum state in the first transfer chamber 22-A is disrupted. Because of the disruption, a conventional vacuum system SYS is required to have the wafer W be removed from a chamber, having a higher vacuum pressure, when a chamber, having a lower vacuum pressure, is vented to atmosphere.

In a preferred embodiment of the present invention, when the first sputtering treatment chamber 42-A is vented to atmosphere, the gate valve GV2 of the first gate lock chamber 70-A is closed. The gate valve GV2 closes unidirectionally from the direction of a higher vacuum pressure to a lower vacuum pressure by utilizing the differential pressure. Therefore, the first transfer chamber 22-A is not vented to atmosphere. As a result, wafers W in other chambers need not to be retrieved and only the first sputtering treatment chamber is vented to atmosphere.

The Configuration of Vacuum Piping and Pumps

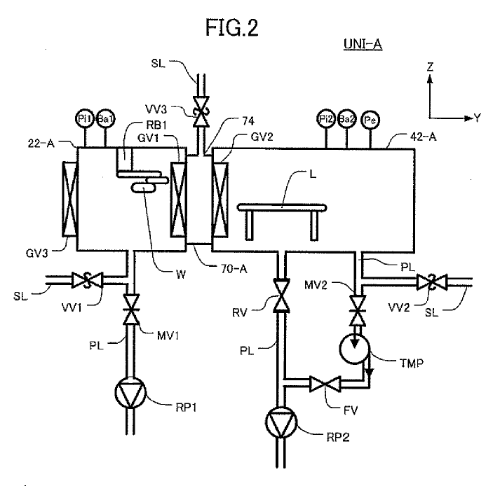

FIG. 2 shows the configuration of piping and pumps for evacuating the first transfer chamber 22-A and the first processing unit UNI-A. Although it is not shown in the diagram, the same configuration of piping and pumps is used for evacuating the second processing unit UNI-B. The vacuum pressure of the first sputtering treatment chamber 42-A is set to, for example, about 1×10-3 Pa. The vacuum pressure of the first transfer chamber 22-A is set to, for example, about 1×100 Pa, which is three orders of magnitude higher than the vacuum pressure in the first sputtering chamber. The first transfer chamber 22-A comprises an atmospheric pressure sensor Ba-1 and a Pirani gauge Pi-1 to measure if the pressure inside the first transfer chamber 22-A is atmospheric, or not. The first sputtering process chamber 42-A comprises an atmospheric pressure sensor Ba-2 and a Pirani gauge Pi-2 to measure if the pressure inside the first sputtering process chamber 42-A is atmospheric, or not, and a Penning gauge Pe to measure lower vacuum pressures. The atmospheric pressure sensors Ba-1 and Ba-2 are used when venting each chamber to atmosphere.

A rotary pump RP1 is disposed on a purge gas line PL in the uppermost stream of the first transfer chamber 22-A. The first rotary pump operates from atmospheric pressure. One first rotary pump is sufficient to create a vacuum in the range of 1×10-1 Pa in the first transfer chamber 22-A. Generally, the ultimate pressures achieved by rotary pumps are in the range of 10 Pa to 1×10-1 Pa. The down stream of the first rotary pump RP1 is connected to the first transfer chamber 22-A, via a first main valve MV1. In the down stream of the first main valve MV1, there is provided a gas supply line SL comprising a vent valve VV1, to supply nitrogen and such when venting to atmosphere.

In addition, there is provided a second rotary pump RP2 on the purge gas line PL in the uppermost stream of the first sputtering treatment chamber 42-A. The second rotary pump RP2 is used for pre-evacuating the first sputtering treatment chamber 42-A, which requires a lower vacuum pressure. The purge gas line PL is further branched into two lines. The first branch of the purge gas line PL is connected to the first sputtering treatment chamber 42-A, via a roughing valve RV. The second branch of the purge gas line PL is connected to the first sputtering treatment chamber 42-A, via a forward valve FV, a turbo-molecular pump TMP and a second main valve MV2.

The turbo-molecular pump TMP comprises metallic vanes to exhaust air to an ultimate vacuum pressure of about 10-6 Pa. Because the operating pressure of the turbo-molecular pump TMP is limited, the turbo-molecular pump TMP is evacuated first to a certain vacuum pressure by the second rotary pump. In the down stream of the second main valve MV2, there is provided a gas supply line SL comprising a vent valve VV2, to supply nitrogen and such when venting to atmosphere.

The first gate lock chamber 70-A, enclosed by the gate valve GV1 and the gate valve GV2, has a gas supply line SL comprising a vent valve VV3 to supply nitrogen and such. The vent valve VV3 is opened to vent the first gate lock chamber 70-A to atmosphere, when the first transfer chamber 22-A and the first sputtering treatment chamber 42-A are under atmospheric pressure, e.g., for the purpose of maintenance service, while the first gate lock chamber 70-A is in a vacuum.

Evacuating Operation

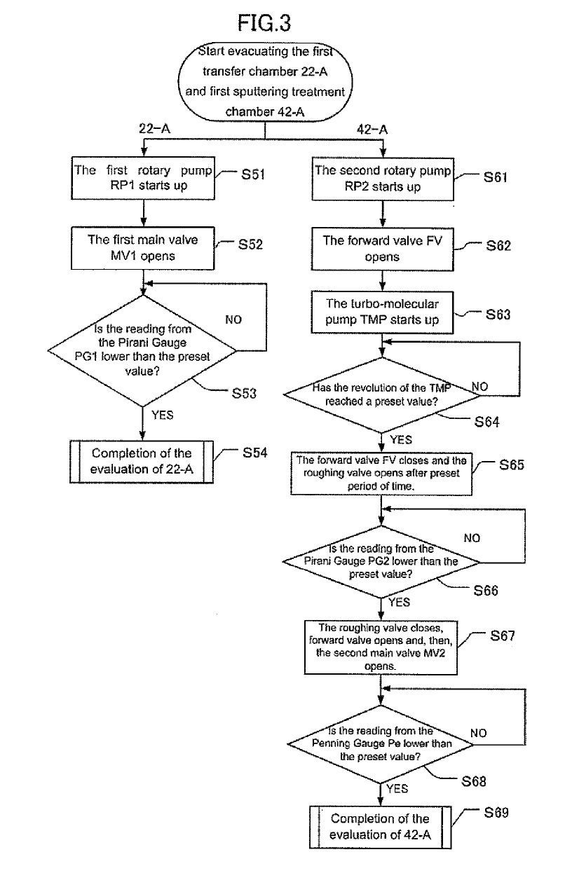

FIG. 3 is a flow chart showing the evacuating operation of the first transfer chamber 22-A and the first sputtering treatment chamber 42-A. The flow chart is based on an evacuating operation starting with all the valves closed. The step S51 is explained first, although step 51 and step 61 may start simultaneously.

For the first transfer chamber 22-A, the first rotary pump starts up in the step 51. In the step 52, the first main valve MV1 is opened to evacuate the first transfer chamber 22-A. In the step 53, vacuum pressure is measured by the Pirani gauge Pi-1, until a predetermined vacuum pressure is reached, and the evacuation stops once the predetermined vacuum pressure is reached.

For the first sputtering treatment chamber 42-A, the second rotary pump RP2 starts up in the step 61. In the step 62, the forward valve FV is opened after a predetermined period of time, and the turbo-molecular pump TMP starts up in the step 63. In the step 64, a judgment is made as to whether the turbo-molecular pump TMP is rotating at a predetermined revolution.

When the rotation of the turbo-molecular pump TMP reaches to a predetermined revolution, the forward valve FV is closed and, after predetermined period of time, the roughing valve RV is opened. This opens the roughing valve RV and the first sputtering treatment chamber 42-A is evacuated by the second rotary pump RP2. In the step 66, the vacuum pressure is measured by the Pirani gauge Pi-2 until a predetermined vacuum pressure is reached. In the step 67, after the predetermined vacuum pressure is reached, the roughing valve RV is closed, the forward valve FV is opened and, after a while, the second main valve MV2 is opened. This allows the first sputtering treatment chamber 42-A being evacuated by the turbo-molecular pump TMP. In the step 68, vacuum pressure is measured by the Penning gauge Pe, until a predetermined vacuum pressure is reached, and the evacuation stops once the predetermined vacuum pressure is reached.

The Configuration of the Gate Lock Chamber 70

### First Embodiments

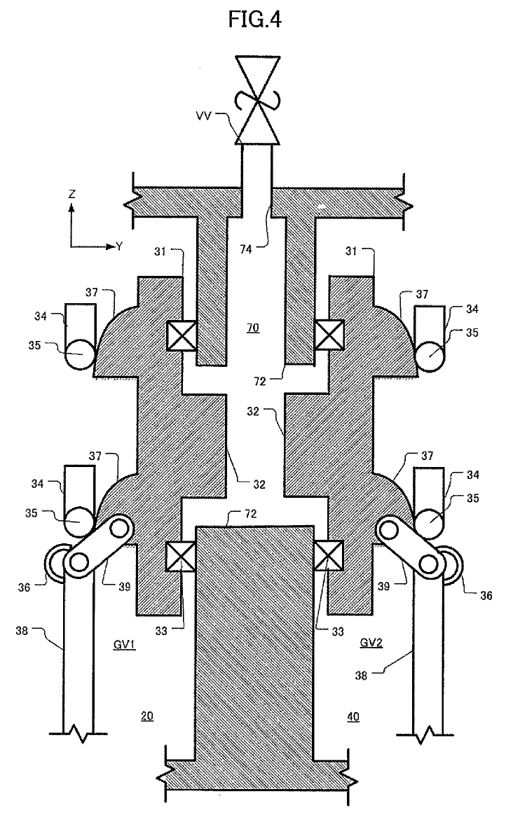

FIG. 4 shows a cross sectional view of the gate valve GV and gate lock chamber 70 according to a first embodiment. The gate lock chamber 70 comprises a rectangular, or a circular, opening window 72. The quartz wafer W, mounted on the fork portion of the transfer robot RB1, passes through the opening window 72 and is transferred from the first transfer chamber 22-A to the first sputtering treatment chamber 42-A. The gate lock chamber 70 comprises an opening hole 74 communicating with atmosphere. The opening hole 74 is connected to the gas line SL, which comprises a vent valve VV3. The pressure inside the gate lock chamber 70 is controlled by controlling the vent valve VV3.

Because the gate valve GV1 and gate valve GV2 have substantially the same structure, same reference numerals are given to corresponding parts in FIG. 3.

The lids 31 have projecting portions 32, one of which protruding from the side of the first transfer chamber 22-A to the side of the gate lock chamber 70 and the other protruding from the side of the first sputtering treatment chamber 42-A to the side of the gate lock chamber 70. The projecting portion 32 is provided to reduce the inner volume of the gate lock chamber 70. The smaller the volume, the less the period of time is required to evacuate and higher the operation efficiency becomes.

The lid 31 comprises three or four cams 37, only two of which are shown in FIG. 4. The cam 37 contacts with the roller 35 of a support 34 from the gate lock chamber 70. The lid 31 of the gate valve GV comprises a groove at the portion contacting the wall of the gate lock chamber 70, and there is placed an O-ring 33 in the groove. A groove may be formed in the wall of the gate lock chamber 70 to place the O-ring 33 on the gate lock chamber 70.

A crank 39 is attached to a portion of the lid 31 in a rotatable manner and a rotatable connecting rod 38 is attached to the crank 39. An elastic member 36, comprising a spring and such, is provided to the crank 39 and connecting rod 38. The elastic member 36 exerts force to stretch the crank 39 and connecting rod 38 in line. On the lower side of the connecting rod 38, an actuator (not shown in the figure) is provided to move the lid 31 up and down.

The vent valve VV3, provided at the opening hole 74 of the gate lock chamber 70, is opened to vent the gas inside the gate lock chamber to atmospheric pressure. For example, in case that the first transfer chamber 22-A and the first sputtering treatment chamber 42-A are vented to atmosphere and the gate lock chamber 70 has a vacuum inside, the gate valve GV1 and gate valve GV2 may not be opened. In such a case, the vent valve VV3 is opened to vent the gate lock chamber 70 to atmosphere.

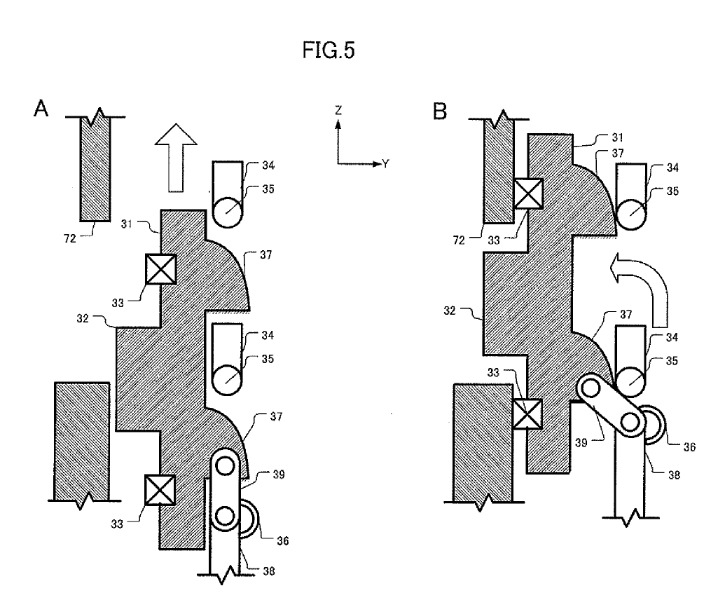

FIG. 5 shows an operation of the gate valve according to a first embodiment. FIG. 5 A shows a transition state, in which the gate valve GV moves to closed state, when the opening window 72 of the gate lock chamber 70 is opened. FIG. 5 A shows a state, in which the opening window 72 is closed by the gate valve GV.

The lid 31 moves from the −Z direction to the +Z direction by the crank 39 and connecting rod 38 attached thereto. The crank 39 and connecting rod 38 are stretched linearly by the elastic member 36. When the lid moves in the +Z direction, the cam 37 contacts with the roller 35. When the cam 37 contacts with the roller 35, the lid 31 moves in the Y direction along the circumference of the cam 37. The elastic member 36 is bent by a pressure smaller than the pressing force of the connecting rod 38. When the lid is moved in the +Z direction and the roller 35 is moved to the apex of the cam 37 by the connecting rod 38, the O-ring 33 contacts closely with the wall of the gate lock chamber 70. The sealing by the lid 31 is thus completed as shown in FIG. 4B.

The above described procedure is reversed when the gate valve GV makes the opening window 72 from a close state to an open state. Incidentally, in FIG. 4 and FIG. 5, the motion in the Z direction of the lid 31 is converted into the motion in the Y direction, however, other mechanism, such as guide mechanism, may be used to produce the same motions.

### Second Embodiments

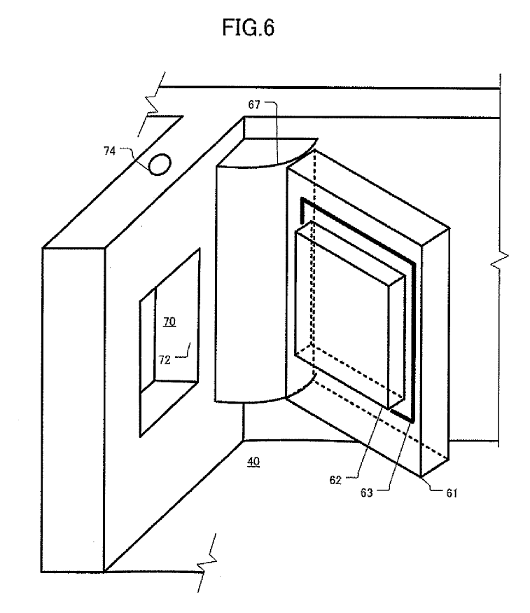

FIG. 6 is a perspective view showing the gate valve GV and the gate lock chamber 70 according to a second embodiment. Incidentally, FIG. 6 shows the gate valve GV2 only, on the side of the first sputtering treatment chamber 42-A, having a lower vacuum pressure. The gate valve configures a door shape, in which the door portion 61 is made pivotable around the hinge portion 67. An actuator, such as a motor attached to the hinge portion 67, turns the door portion 61 against the wall of the gate lock chamber 70 and, thus, closes the opening window 72. The lids 61 of the gate valve GV have a projecting portion 62, protruding from the side of the first transfer chamber 22-A to the side of the gate lock chamber 70, or protruding from the side of the first sputtering treatment chamber 42-A to the side of the gate lock chamber 70. The door portion 61 of the gate valve GV comprises a groove at the portion contacting the wall of the gate lock chamber 70, and there is placed an O-ring 63 in the groove. An opening hole 74 having a vent valve VV3 is provided to protect the O-ring 63, when opening and closing the door portion 61. The pressure inside the gate lock chamber 70 is controlled by opening the vent valve VV3.

### INDUSTRIAL APPLICABILITY

In the above embodiments, chambers for sputtering have been explained as chambers, having lower vacuum pressures, for exemplary purpose, however, it is needless to say that other types of chambers are applicable. Further, a gate lock chamber may be disposed between a transfer chamber and another transfer chamber having different pressures, as in the case of the gate lock chambers 70-C and 70-D, as shown in FIG. 1.

What is claimed:

1. A vacuum processing apparatus comprising;
a first vacuum chamber having a predetermined vacuum pressure;
a second vacuum chamber being different from the first vacuum chamber;
a gate lock chamber connecting the first vacuum chamber and the second vacuum chamber;
a first gate valve opening and closing between the first vacuum chamber and the gate lock chamber; and
a second gate valve opening and closing between the second vacuum chamber and the gate lock chamber.

2. The vacuum processing apparatus disclosed in claim 1, wherein;
the vacuum pressure of the first vacuum chamber is higher than the vacuum pressure of the second vacuum chamber.

3. The vacuum processing apparatus disclosed in claim 1, wherein;
the gate lock chamber comprising a pipeline connected to atmosphere and a valve opening and closing the pipeline.

4. The vacuum processing apparatus disclosed in claim 2, wherein;
the gate lock chamber comprising a pipeline connected to atmosphere and a valve opening and closing the pipeline.

5. The vacuum processing apparatus disclosed in claim 1, wherein;
at least one of the first gate valve and the second gate valve having at least a projecting portion protruding toward the side of the gate lock chamber.

6. The vacuum processing apparatus disclosed in claim 2, wherein;
at least one of the first gate valve and the second gate valve having at least a projecting portion protruding toward the side of the gate lock chamber.

7. The vacuum processing apparatus disclosed in claim 3, wherein;
at least one of the first gate valve and the second gate valve having at least a projecting portion protruding toward the side of the gate lock chamber.

8. The vacuum processing apparatus disclosed in claim 4, wherein;
at least one of the first gate valve and the second gate valve having at least a projecting portion protruding toward the side of the gate lock chamber.

9. The vacuum processing apparatus disclosed in claim 1, further comprising;
a sealing member disposed between the first gate valve and the first vacuum chamber and/or between the second gate valve and the second vacuum chamber.

10. The vacuum processing apparatus disclosed in claim 2, further comprising;
a sealing member disposed between the first gate valve and the first vacuum chamber and/or between the second gate valve and the second vacuum chamber.

11. The vacuum processing apparatus disclosed in claim 3, further comprising;
a sealing member disposed between the first gate valve and the first vacuum chamber and/or between the second gate valve and the second vacuum chamber.

12. The vacuum processing apparatus disclosed in claim 4, further comprising;
a sealing member disposed between the first gate valve and the first vacuum chamber and/or between the second gate valve and the second vacuum chamber.

13. The vacuum processing apparatus disclosed in claim 5, further comprising;
a sealing member disposed between the first gate valve and the first vacuum chamber and/or between the second gate valve and the second vacuum chamber.

14. The vacuum processing apparatus disclosed in claim 6, further comprising;
a sealing member disposed between the first gate valve and the first vacuum chamber and/or between the second gate valve and the second vacuum chamber.

15. The vacuum processing apparatus disclosed in claim 7, further comprising;
a sealing member disposed between the first gate valve and the first vacuum chamber and/or between the second gate valve and the second vacuum chamber.

16. The vacuum processing apparatus disclosed in claim 8, further comprising;
a sealing member disposed between the first gate valve and the first vacuum chamber and/or between the second gate valve and the second vacuum chamber.

17. A method, provided with a first vacuum chamber, having a predetermined vacuum pressure, and a second vacuum chamber, having a vacuum pressure lower than the predetermined vacuum pressure, for venting only the second vacuum chamber to atmosphere, comprising steps of:
disposing a first gate valve opening and closing between the first vacuum chamber and a gate lock chamber that connects the first vacuum chamber with the second vacuum chamber;
disposing a second gate valve on the gate lock chamber, opening and closing between the second vacuum chamber and the gate lock chamber; and
supplying gas from a vent valve on the second vacuum chamber.
